(19) United States
(12) Patent Application Publication
(10) Pub. No.: US 2024/0213176 A1
(43) Pub. Date: Jun. 27, 2024

(54) IDENTIFICATION INFORMATION ACQUISITION METHOD, PATTERN FORMING METHOD, SEMICONDUCTOR MANUFACTURING FACILITY OPERATION METHOD, PROCESSING APPARATUS, AND PATTERN FORMING APPARATUS

(71) Applicant: CANON KABUSHIKI KAISHA, Tokyo (JP)

(72) Inventor: YOSHIHITO TADA, Tochigi (JP)

(21) Appl. No.: 18/537,128

(22) Filed: Dec. 12, 2023

(30) Foreign Application Priority Data
Dec. 20, 2022 (JP) 2022-203527

(51) Int. Cl. H01L 23/544; H01L 21/66

(52) U.S. Cl. CPC H01L 23/544; H01L 22/30; H01L 2223/54433

(57) ABSTRACT

An acquisition method of acquiring identification information of a substrate from measurement results of a plurality of patterns formed on the substrate is provided. The method includes specifying the identification information based on first information extracted, in accordance with a first rule, from respective positions of regions where the plurality of patterns respectively exist and second information extracted from respective states of the plurality of patterns in accordance with a second rule.

### BACKGROUND OF THE INVENTION

### Field of the Invention

The present invention relates to an identification information acquisition method, a pattern forming method, a semiconductor manufacturing facility operation method, a processing apparatus, and a pattern forming apparatus.

### Description of the Related Art

Japanese Patent Laid-Open No. 2008-218594 discloses a method of identifying a wafer using an intentionally generated overlay error.

In the method of Japanese Patent Laid-Open No. 2008-218594, both an apparatus for generating an overlay deviation corresponding to identification information and an apparatus for detecting the identification information from a deviation amount share information about a special shot region called a marking shot.

### SUMMARY OF THE INVENTION

The present invention provides a technique advantageous in providing information from one apparatus to another apparatus via a substrate.

One of aspects of the present invention provides an acquisition method of acquiring identification information of a substrate from measurement results of a plurality of patterns formed on the substrate, comprising: specifying the identification information based on first information extracted, in accordance with a first rule, from respective positions of regions where the plurality of patterns respectively exist and second information extracted from respective states of the plurality of patterns in accordance with a second rule.

Further features of the present invention will become apparent from the following description of exemplary embodiments with reference to the attached drawings.

### BRIEF DESCRIPTION OF THE DRAWINGS

FIG. 1 is a view schematically showing a wafer to which the present disclosure is applied;

FIG. 2 is a flowchart of processing of extracting identification information from a measured value;

FIG. 3 is a view exemplifying a conversion result of a measurement result;

FIG. 4 is a view exemplifying a measurement mark arrangement;

FIG. 5 is a flowchart of processing of converting coordinates into a position number;

FIG. 6 is a view exemplifying the relationship between the relationship between measurement coordinates and start point coordinates;

FIG. 7 is a flowchart of processing of forming identification information;

FIG. 8 is a view for explaining a method of forming a measurement mark in a shot region;

FIG. 9 is a view schematically showing the configuration of a system serving as a semiconductor manufacturing facility;

FIG. 10 is a view schematically showing a performance inspection wafer;

FIG. 11 is a view schematically showing a wafer produced by exposure processing;

FIG. 12 is a view schematically showing a stage adjustment wafer;

FIG. 13 is a flowchart of wafer selection processing;

FIG. 14 is a view for explaining a method of forming a mark whose measurement result is abnormal;

FIG. 15 is a view for explaining a method of changing the line width of a line width measurement mark;

FIG. 16 is a view exemplifying a wafer produced for performance inspection of an exposure apparatus; and

FIG. 17 is a view exemplifying mark formation information.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

A semiconductor manufacturing facility operation method according to one embodiment can include a pattern forming step of forming a plurality of patterns on a substrate in accordance with a unique pattern forming method, and an acquisition step of acquiring an identification number from the substrate with the formed patterns in accordance with a unique acquisition method.

The pattern forming method can include a first step of determining, in accordance with a first rule, positions on a substrate, where a plurality of patterns are respectively formed on the substrate, and a second step of determining, in accordance with a second rule, states with which the plurality of patterns are respectively formed on the substrate. The pattern forming method can include a third step of forming the plurality of patterns on the substrate in accordance with results determined in the first step and the second step.

The acquisition method acquires identification information of the substrate from measurement results of the plurality of patterns formed on the substrate. The acquisition method can include a step of specifying the identification information based on first information extracted, in accordance with a first rule, from respective positions of regions where the plurality of patterns respectively exist and second information extracted from respective states the plurality of patterns in accordance with a second rule.

In the acquisition method, the respective states of the plurality of patterns can be respective positions of the plurality of patterns. Alternatively, the respective states of the plurality of patterns can be respective line widths of the plurality of patterns.

In the acquisition method, the respective positions of the regions where the plurality of patterns respectively exist can be respective positions of shot regions where the plurality of patterns respectively exist. Alternatively, the plurality of patterns exist in one shot region, and the respective positions of the regions where the plurality of patterns respectively exist can be positions in the one shot region.

In the acquisition method, the second information can include a plurality of indices converted from the respective states of the plurality of patterns, and the first information can include information used to determine an order to arrange the plurality of indices to obtain the identification information using the plurality of indices.

In the acquisition method, in the step, the identification information can be reproduced by combining numbers assigned to the plurality of indices to indicate the order and the plurality of indices. Each of the plurality of indices can have one of values of 2 or more. Alternatively, each of the plurality of indices can have one of values of 3 or more.

In the acquisition method, the second information can include a plurality of indices converted from the respective states of the plurality of patterns. Each of the plurality of indices can be a value obtained by evaluating a position deviation of each of the plurality of patterns with respect to corresponding one of a plurality of reference positions corresponding to the plurality of patterns.

Another embodiment is related to a processing apparatus having a function of acquiring identification information of a substrate from measurement results of a plurality of patterns formed on the substrate. The processing apparatus can execute the acquisition step. The processing apparatus can be, for example, a measurement instrument. Alternatively, the processing apparatus can be an information processing apparatus to which a result of measurement by a measurement instrument is provided. The processing apparatus includes a processor configured to specify the identification information based on first information extracted, in accordance with a first rule, from a position of each of regions where the plurality of patterns exist and second information extracted from the state of each of the plurality of patterns in accordance with a second rule. The processor can be formed by, for example, a Programmable Logic Device (PLD) such as a Field Programmable Gate Array (FPGA), an Application Specific Integrated Circuit (ASIC), a general-purpose or dedicated computer in which a program is installed, or a combination of some or all of these.

Still another embodiment is related to a pattern forming apparatus for forming a plurality of patterns on a substrate. The pattern forming apparatus can execute the pattern forming step. The pattern forming apparatus can be, for example, an exposure apparatus, an imprint apparatus, or an electron-beam exposure apparatus. The pattern forming apparatus can include a processor. The processor can determine, in accordance with a first rule, a position to form each of the plurality of patterns on the substrate, and determine, in accordance with a second rule, a state to form each of the plurality of patterns on the substrate. Also, the processor can control a pattern forming operation to form the plurality of patterns on the substrate in accordance with the determined results. The processor can be formed by, for example, a Programmable Logic Device (PLD) such as a Field Programmable Gate Array (FPGA), an Application Specific Integrated Circuit (ASIC), a general-purpose or dedicated computer in which a program is installed, or a combination of some or all of these.

A more detailed embodiment of the above-described embodiment will be described below. In this embodiment, in a first apparatus (pattern forming apparatus), identification information of a substrate can be reflected as a forming state according to a second rule on a measurement target mark selected from a plurality of measurement target marks on the wafer (substrate) in accordance with a first rule. The identification information is thus recorded on the wafer. Reflection on the forming state indicates that when transferring the pattern of the measurement target mark to the wafer, at least one of features such as a wafer position, an exposure amount, and a transfer target pattern is intentionally changed from a reference state in accordance with the identification information to be reflected on the mark. The first apparatus can determine, in accordance with the first rule, the position to form each of a plurality of patterns on the wafer, determine, in accordance with the second rule, a state to form each of the plurality of patterns on the wafer, and form the plurality of patterns on the wafer in accordance with determined results.

Also, in this embodiment, in a second apparatus (measurement instrument or information processing apparatus), identification information is extracted from measurement results of a wafer on which the identification information is reflected. The second apparatus can specify the identification information of the wafer based on first information extracted, in accordance with a first rule, from respective positions of regions where the plurality of patterns respectively exist and second information extracted from respective states of the plurality of patterns in accordance with a second rule.

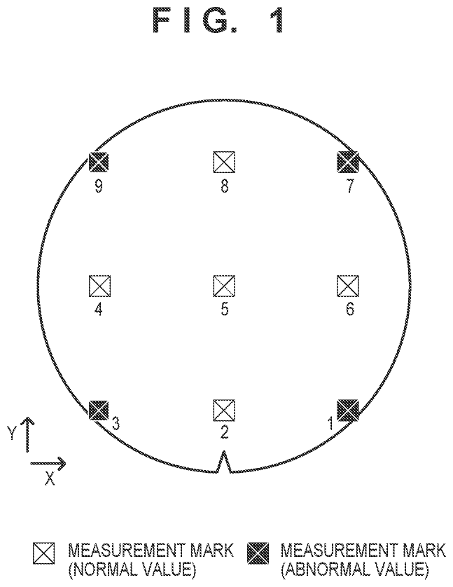

A procedure of extracting identification information from a wafer measurement result in the second apparatus will be described below. FIG. 1 is a view schematically showing an example of a wafer that is the application target of the present disclosure. Measurement target marks exist at a plurality of points, more specifically, at nine points on the wafer. Of these marks, four marks are in forming states that exhibit abnormal values shown in Table 1 at the time of measurement. Note that in Table 1, items in boldface indicate abnormal values. This applies to other tables as well.

TABLE 1
Measurement Coordinates and Measured Values

| Shot | Measurement | Measurement | Measured | Measured |
|---|---|---|---|---|
| No. | Coordinates X | Coordinates Y | Value X | Value Y |
| 1 | Cx(1) | Cy(1) | X(1) | Y(1) |
| 2 | Cx(2) | Cy(2) | X(2) | Y(2) |
| 3 | Cx(3) | Cy(3) | X(3) | Y(3) |
| 4 | Cx(4) | Cy(4) | X(4) | Y(4) |
| 5 | Cx(5) | Cy(5) | X(5) | Y(5) |
| 6 | Cx(6) | Cy(6) | X(6) | Y(6) |
| 7 | Cx(7) | Cy(7) | X(7) | Y(7) |
| 8 | Cx(8) | Cy(8) | X(8) | Y(8) |
| 9 | Cx(9) | Cy(9) | X(9) | Y(9) |

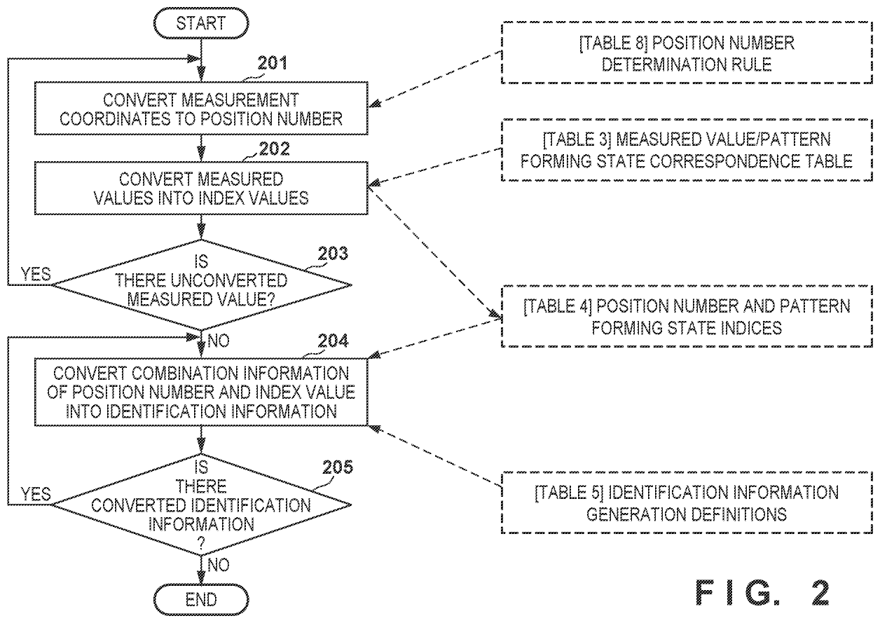

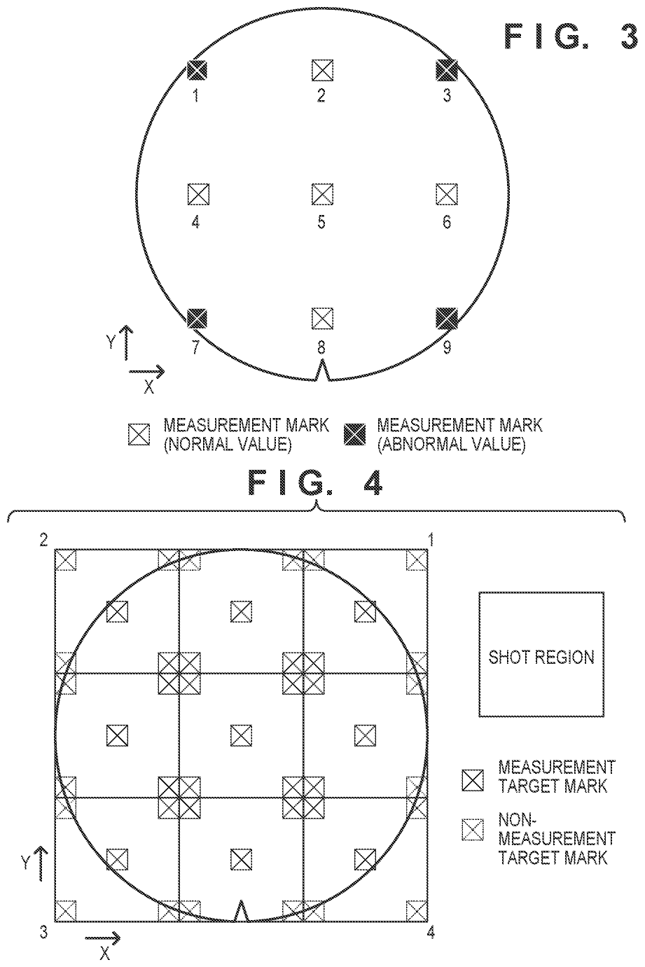

A procedure of the second apparatus obtaining identification information from the result of measuring the wafer in FIG. 1, that is, the information shown in Table 1 will be described with reference to FIG. 2. FIG. 2 is a flowchart of processing executed by (the processor of) the second apparatus. First, the second apparatus converts measurement coordinates in Table 1 into a position number (first information) by conversion processing to be described later, thereby obtaining information shown in FIG. 3 and Table 2 (step 201).

TABLE 2
Measurement Position Numbers and Measured Values

| Position | Measurement | Measurement | Measured | Measured |
|---|---|---|---|---|
| Number | Coordinates X | Coordinates Y | Value X | Value Y |
| 1 | Cx(1) | Cy(1) | X(1) | Y(1) |
| 2 | Cx(2) | Cy(2) | X(2) | Y(2) |
| 3 | Cx(3) | Cy(3) | X(3) | Y(3) |
| 4 | Cx(4) | Cy(4) | X(4) | Y(4) |
| 5 | Cx(5) | Cy(5) | X(5) | Y(5) |
| 6 | Cx(6) | Cy(6) | X(6) | Y(6) |
| 7 | Cx(7) | Cy(7) | X(7) | Y(7) |
| 8 | Cx(8) | Cy(8) | X(8) | Y(8) |
| 9 | Cx(9) | Cy(9) | X(9) | Y(9) |

Next, the second apparatus converts each measured value into an index (second information) using a correspondence table, shown in Table 3, of measured values and pattern forming state indices (to be also referred to as indices hereinafter) each of which is an index representing a pattern forming state (step 202). Note that Table 3 shows the classification methods of measured values including specific ranges. This is merely an example, and the correspondence table of the measured values and the pattern forming state indices need only defines a plurality of classifications and the range of a value belonging to each classification.

TABLE 3
Measured Value and Pattern Forming State
Index Value Correspondence Table

| | | | | Pattern |
|---|---|---|---|---|
| | Measured Value X | Representative | | Forming |
| Classification | Range | Value | | State Index |
| Normal Value | −30 nm ≤ X ≤ 30 nm | 0 | nm | 0 |
| Abnormal | X < −60 nm | −100 | nm | 1 |
| Value 1 | | | | |
| Abnormal | −60 nm ≤ X < −30 nm | −45 | nm | 2 |
| Value 2 | | | | |
| Abnormal | 30 nm < X ≤ 60 nm | 45 | nm | 3 |
| Value 3 | | | | |
| Abnormal | 60 nm < X | 100 | nm | 4 |
| Value 4 | | | | |
| Normal Value | −30 nm ≤ Y ≤ 30 nm | 0 | nm | 0 |
| Abnormal | Y < −30 nm | −50 | nm | 1 |
| Value 1 | | | | |
| Abnormal | 30 nm < Y | 50 | nm | 1 |
| Value 2 | | | | |

Here, the second apparatus confirms the presence/absence of a measured value that is not converted into the combination of a position number (first information) and an index (second information) (step 203), and if an unconverted measured value exists, returns to the processing of converting measurement coordinates into a position number (step 201). If all measured values are converted in accordance with the rules shown in Table 3, information shown in Table 4 can be obtained.

TABLE 4
Position Numbers and Pattern Forming State Indices

| | |
|---|---|
| | Pattern |
| | Forming State |
| Position | Index |

| Number | Index X | Index Y |
|---|---|---|
| 1 | 1 | 0 |
| 2 | 0 | 0 |
| 3 | 2 | 0 |
| 4 | 0 | 0 |
| 5 | 0 | 0 |
| 6 | 0 | 0 |
| 7 | 3 | 0 |
| 8 | 0 | 0 |
| 9 | 4 | 1 |

| | Position Number | | | | | | | | |
|---|---|---|---|---|---|---|---|---|---|
| | 1 | 2 | 3 | 4 | 5 | 6 | 7 | 8 | 9 |
| Index X | 1 | 0 | 2 | 0 | 0 | 0 | 3 | 0 | 4 |
| Index Y | 0 | 0 | 0 | 0 | 0 | 0 | 0 | 0 | 1 |

A procedure of the second apparatus generating identification information from the information shown in Table 4 will be described next (step 204). In Table 4, nine position numbers, nine indices X, and nine indices Y, that is, a total of 27 pieces of information exist as the information obtained by converting measurement results at nine points. These pieces of information are elements used to generate one or more pieces of identification information, and identification information can be obtained by performing predetermined character string generation processing for the information shown in Table 4.

Table 5 shows an example of definition information for defining character string generation processing, and character string generation processing for obtaining two pieces of identification information from the information shown in Table 4 is defined.

TABLE 5
Identification Information Generation Definitions

| | Arrangement | | | |
|---|---|---|---|---|
| | Order of | | | |
| | Position | | Generation | |
| | Numbers | Use Information | Result | Meaning |
| Identification | ascending | only abnormal | 11327394 | wafer number |
| Information 1 | order | value \| position | | |
| | | numbers, index X | | |
| Identification | descending | all data \| index Y | 100000000 | 0: measurable |
| Information 2 | order | | | ≠0: unmeasurable |

A procedure of executing character string generation processing according to the definition information shown in Table 5 for the information shown in Table 4 to acquire identification information will be described. Table 5 defines character string generation processing for generating two pieces of identification information.

First, the generation procedure of first identification information 1 will be described. Since the arrangement order based on the position numbers is an ascending order, it is shown that the position numbers are arranged sequentially from a measurement position with a small position number. Pieces of information used as identification information 1 are the position number and the index X of an abnormal value. Here, position numbers for abnormal values are 1, 3, 7, and 9. Since the indices X are 1, 2, 3, and 4, arranging the pairs of position numbers and indices X in the ascending order of position numbers results in 11327394.

Next, the generation procedure of identification information 2 will be described. Since the arrangement order based on the position numbers is a descending order, it is shown that the position numbers are arranged sequentially from a measurement position with a large position number. Pieces of information used as identification information 2 are the index Y of all data. Here, arranging only all indices Y in the descending order of position numbers results in 100000000.

Note that the contents described in Table 5 are merely examples. Since how to combine the position number, the index X, and the index Y to generate identification information need only be defined, the present invention is not limited to the format and described contents in Table 5.

The procedure of obtaining one or more pieces of identification information from the result of measuring a wafer has been described above. The processing of converting measurement coordinates into a position number will be described here anew. FIG. 4 shows a wafer as an application target of this embodiment, and several measurement target marks are formed in a state in which an intentional formation error is caused in accordance with the gist of this embodiment. Table 6 shows a result obtained by measuring the wafer. The measurement coordinates of this measurement result are defined on a coordinate system whose origin coordinates are located at “3” (the lower left corner of the lower left shot region) in FIG. 4, and the directions of coordinate axes are the directions of arrows in FIG. 4. Note that in this embodiment, the coordinate system is not particularly limited. This example is an example of processing of converting coordinates into a position number, and only clarifying the origin coordinates and the directions of coordinate axes suffices.

TABLE 6
Measurement Result Data

| Measurement | Measurement | Measured | Measured |
|---|---|---|---|
| Coordinates X | Coordinates Y | Value X | Value Y |
| Cx(1) | Cy(1) | Mx(1) | My(1) |
| Cx(2) | Cy(2) | Mx(2) | My(2) |
| Cx(3) | Cy(3) | Mx(3) | My(3) |
| Cx(4) | Cy(4) | Mx(4) | My(4) |
| Cx(5) | Cy(5) | Mx(5) | My(5) |
| . | . | . | . |
| . | . | . | . |
| . | . | . | . |

Table 7 shows the relationship between measured value coordinates and position numbers. In an initial state, all position numbers are unset.

TABLE 7
Coordinate and Position Number Correspondence Table

| Measurement | Measurement | Position |
|---|---|---|
| Coordinates X | Coordinates Y | Number |
| Cx(1) | Cy(1) | LocNo(1) |
| Cx(2) | Cy(2) | LocNo(2) |
| Cx(3) | Cy(3) | LocNo(3) |
| Cx(4) | Cy(4) | LocNo(4) |
| Cx(5) | Cy(5) | LocNo(5) |
| . | . | . |
| . | . | . |
| . | . | . |

Table 8 shows rules for converting measurement mark coordinates into a position number. Contents include a position serving as a start point when assigning a position number, and a priority coordinate axis used to add an order to a measurement mark.

TABLE 8
Position Number Determination Rules

| | |
|---|---|
| Position Number Reference Point | designate from 1 to 4 |
| First Coordinate Axis | X or Y (different from |
| | second coordinate axis) |
| Second Coordinate Axis | X or Y (different from |
| | first coordinate axis) |

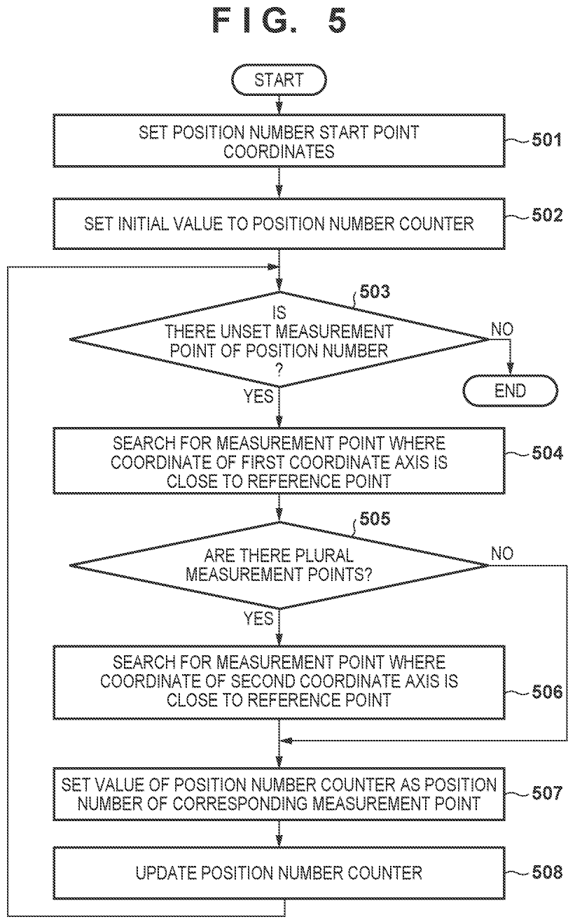

A procedure of setting the position numbers in Table 7 using Table 8 will be described next with reference to FIG. 5. First, as preparation processing, the second apparatus sets coordinates (start point coordinates) serving as the start point of a position number (step 501). The setting of the start point coordinates is executed in accordance with the following procedure.

First, based on the direction of the coordinates of a measured value, which one of quadrants (1, 2, 3, and 4 in FIG. 4) should be used to place the start point coordinates to assign a position number, and the directions of the XY coordinate system, the signs of X- and Y-coordinates of the start point coordinates are determined from Table 9. Also, which one of the X- and Y-coordinate values should be used with priority when determining the position number is determined.

TABLE 9
Quick Reference Table for Signs of Position
Number Start Point Coordinates

| | Reference Point X- | | | Reference Point Y- | |
|---|---|---|---|---|---|
| | coordinate Sign | | | coordinate Sign | |
| | X-coordinate | | | Y-coordinate | |
| | Direction | | | Direction | |
| Start | 2→1, | 1→2, | Start | 3→2, | 2→3, |
| Quadrant | 3→4 | 4→3 | Quadrant | 4→1 | 1→4 |
| 1 | + | − | 1 | + | − |
| 2 | − | + | 2 | + | − |
| 3 | − | + | 3 | − | + |
| 4 | + | − | 4 | − | + |

Position Number Determination Rules (Example)

| | |
|---|---|
| Position Number Reference Point | 2 |
| First Coordinate Axis | Y |
| Second Coordinate Axis | X |

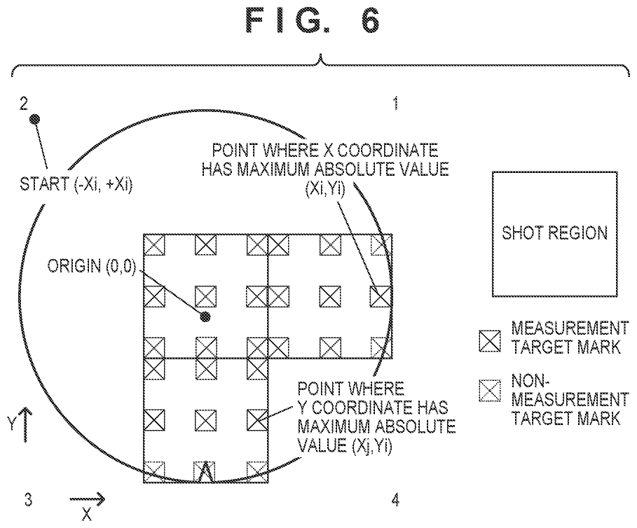

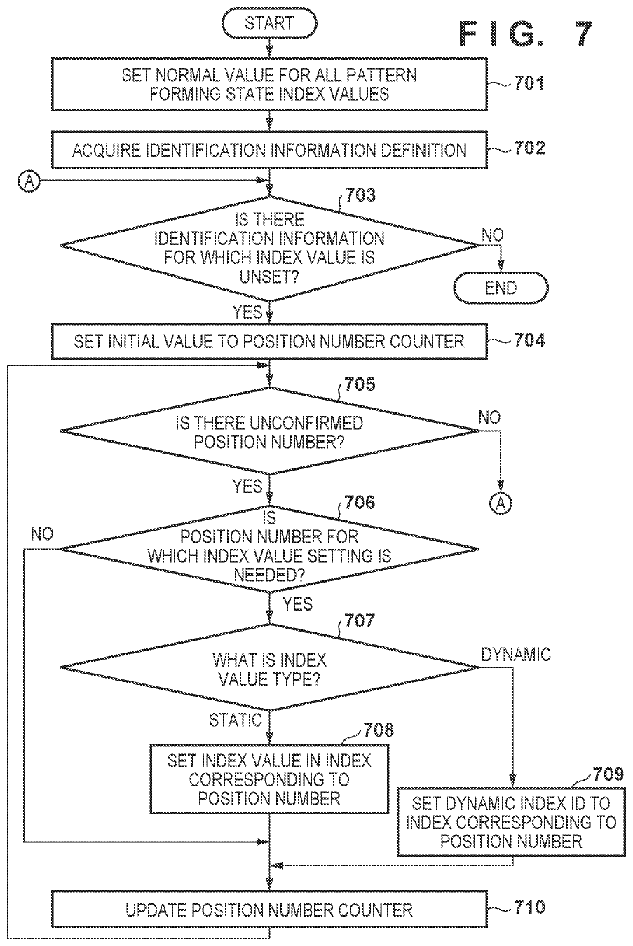

Coordinate values whose absolute values are maximum are specified from the coordinate values of X- and Y-coordinates of all measured values, and the signs of start point coordinates are set for the maximum absolute values, thereby generating start point coordinates. The start point coordinates generated by this processing are located on the outermost side of the quadrant serving as the start point. Note that FIG. 6 shows, as an example, the relationship between the measurement coordinates and the start point coordinates when the quadrant to place the start point coordinates is 2.

Next, the second apparatus sets an initial value to a position number counter (step 502). The preparation processing thus ends, and processing of setting a position number for measurement coordinates is performed from then on.

First, the second apparatus refers to Table 7 and confirms whether there is a measurement position whose position number is unset (step 503). If there is no measurement position whose position number is unset, the processing is ended. If there is a measurement position whose position number is unset, the second apparatus searches for a measurement position for which the coordinate values on the first coordinate axis in Table 8 are closest to the coordinate values of the start point of a position number (step 504). Next, it is determined whether there are a plurality of such measurement positions (step 505). If there is one measurement position, the second apparatus sets the measurement position to a position number setting target, and advances to next processing (step 507). If there are a plurality of such measurement positions, the second apparatus sets a measurement position for which the coordinate values on the second coordinate axis in Table 7 are closest to the coordinate values of the start point of a position number to a position number setting target (step 506). Next, the second apparatus sets the value of the position number counter to the position number of the measurement coordinates that is the position number setting target in Table 7 (step 507). After that, the second apparatus updates the position number counter (step 508) and returns to the processing of confirming whether there is a measurement position whose position number is unset (step 503). With the above-described processing, a position number corresponding to measurement mark coordinates on the wafer is set.

As described above, the second apparatus can acquire a position number from the coordinates of a measurement mark by the processing shown in FIG. 5, and extract identification information included in the measured value from the position number (first information) and an index value (second information) representing the forming state of the measurement mark by the processing shown in FIG. 2.

An identification information forming procedure that is another aspect of the present disclosure will be described next. The identification information forming procedure is executed by the first apparatus. Formation of identification information is executed at the time of exposure processing of a shot region. To do this, information about exposure processing for forming identification information, that is, what kind of exposure processing should be executed at which position needs to be defined in advance. A procedure of setting information for defining an exposure processing method based on identification information formed on a wafer will be described with reference to FIG. 7. FIG. 7 shows an identification information forming procedure executed by the first apparatus.

First, the first apparatus sets, in a table (Table 10 before setting) for designating a measurement mark forming state for each position number, a value indicating that special pattern formation for identification information is unnecessary (the value is 0 in this example, but can be fixed to an arbitrary value) (step 701).

Next, the first apparatus 1 acquires an identification information definition (Table 11) representing the configuration of identification information (step 702). The identification information definition need only clarify the following information and is not limited to the example shown here.
The position of each measurement mark (index) used to record identification information
The type of an index to be reflected when forming each measurement mark (for example, static or dynamic)
The arrangement order of indices corresponding to position numbers (for example, ascending order or descending order).

An additional explanation will be made here concerning the index type. The identification information includes static information such as a wafer ID and dynamic information such as a processing result that changes in accordance with a situation. For example, in a case where whether a wafer process is possible is expressed by two types of indices, and this is formed as identification information, the index value cannot be determined in advance because it is dynamic information. As for the dynamic index, definition is done in advance only for the forming position and an index value according to the situation.

Next, if there exists identification information that needs index value setting (“exists” in step 703), the first apparatus initializes the position number counter and starts index value setting in Table 10 (step 704). First, the first apparatus determines whether an unconfirmed position number remains at the start of a setting processing loop using position numbers (step 705). If no unconfirmed position number remains, the process advances to setting processing for next identification information (transition A). Next, for the unconfirmed position number, the first apparatus determines whether the current position number (the counter of the setting processing loop) is a position number that needs index value setting (step 706). The necessity determination can be executed in accordance with the identification information definition (Table 11) (first rule).

The format of identification information 1 in Table 11 includes four connected pairs of a one-digit position number and a one-digit index X, and “11327394” is designated as information to be generated. Hence, it is found that position numbers 1, 3, 7, and 9 are targets to form special measurement marks, and index values to be set are 1, 2, 3, and 4.

Referring back to FIG. 7, its index value setting needs to be performed, the first apparatus determines the type of the index value setting in accordance with the identification information definition (Table 11) (step 707). If the type is the static index value, the first apparatus sets an index value indicating the forming state of a measurement mark (step 708). If the type is the dynamic index value, the first apparatus sets a value ((a) in Tables 10 and 11, but the value is not limited to this) indicating that the index value is determined in accordance with the situation at the time of exposure processing (step 709). Next, the first apparatus updates the position number counter (step 710) and advances to processing of the next position number. By applying the above-described processing to all position numbers, the first apparatus completes a table (Table 10 after setting) that defines how to execute exposure processing in exposure processing of a measurement mark corresponding to the position number.

TABLE 10
Position Numbers and Pattern Forming State Indices

| | | | |
|---|---|---|---|
| | Before Setting | | After Setting |
| | Pattern Forming | | Pattern Forming |
| Position | State Index | Position | State Index |

| Number | Index X | Index Y | Number | Index X | Index Y |
|---|---|---|---|---|---|
| 1 | 0 | 0 | 1 | 1 | 0 |
| 2 | 0 | 0 | 2 | 0 | 0 |
| 3 | 0 | 0 | 3 | 2 | 0 |
| 4 | 0 | 0 | 4 | 0 | 0 |
| 5 | 0 | 0 | 5 | 0 | 0 |
| 6 | 0 | 0 | 6 | 0 | 0 |
| 7 | 0 | 0 | 7 | 3 | 0 |
| 8 | 0 | 0 | 8 | 0 | 0 |
| 9 | 0 | 0 | 9 | 4 | (a) |
| . | . | . | . | . | . |
| . | . | . | . | . | . |
| . | . | . | . | . | . |
| n | 0 | 0 | n | 0 | 0 |

TABLE 11
Identification Information Definition

| | Arrangement | | | | |
|---|---|---|---|---|---|
| | Order of | Position | | | |
| | Position | Number | Index | Generated | |
| | Numbers | Format | Type | Information | Meaning |
| Identification | ascending | {{position | static | 11327394 | wafer |
| Information | order | number[1]> | | | number |
| 1 | | <(index X | | | |
| | | (only | | | |
| | | abnormal)[1]>} | | | |
| | | (4) | | | |
| Identification | descending | {index | dynamic | (a)00000000 | 0: Measurable |
| Information | order | Y(ALL)[1]>} | | | ≠0: Unmeasurable |
| 2 | | (9) | | | |

When forming a pattern on a wafer by an exposure apparatus, exposure processing of a small region called a shot region is repeated, thereby implementing exposure of the whole surface of the wafer. Hence, before the exposure processing, it is necessary to clarify the relationship between a shot region and a position number and make it possible to, when executing shot region exposure, execute exposure processing considering the position number (first information) and the index value (second information) indicating the pattern forming state.

An application method of shot region processing will be described below. First, the first apparatus creates information (Table 12) for controlling shot region processing.

TABLE 12
Definition of Position Number Processing
Method for Shot Processing

| | | Measure- | Measure- | | | |
|---|---|---|---|---|---|---|
| | | ment | ment | | | |
| | | Coordi- | Coordi- | | | |
| Shot | Mark | nates | nates | Position | | Mark |
| No. | No. | X | Y | Number | Index | Processing |
| 1 | 1 | Cx(1) | Cy(1) | LocNo(1) | Idx(1) | MkExp(1) |
| | . | . | . | . | . | . |
| | . | . | . | . | . | . |
| | . | . | . | . | . | . |
| | m | Cx(m) | Cy(m) | LocNo(m) | Idx(m) | MkExp(m) |
| . | . | . | | . | . | . |
| . | . | . | | . | . | . |
| . | . | . | | . | . | . |
| S | 1 | Cx(z − | Cy(z − | LocNo(z − | Idx(z − | MkExp(z − |
| | | n + 1) | n + 1) | n + 1) | n + 1) | n + 1) |
| | . | . | . | . | . | . |
| | . | . | . | . | . | . |
| | . | . | . | . | . | . |
| | n | Cx(z) | Cy(z) | LocNo(z) | Idx(z) | MkExp(z) |

First, based on information such as a recipe of the exposure apparatus, the first apparatus extracts measurement marks included in each shot region and coordinates thereof. In Table 12, m measurement marks exist in a first shot region, n measurement marks exist in an Sth shot region, and the total number of measurement marks in all shot regions is z.

Next, the first apparatus determines a position number corresponding to extracted measurement mark coordinates in accordance with the procedure shown in FIG. 5. Furthermore, the first apparatus sets information (a value in Table 10 after setting) indicating a measurement mark forming state for each position number as the index value of a mark the position number in Table 12 matches. Here, focusing a plurality of index values for the same Shot No., a value is set for mark processing. The index value indicates how to perform exposure, for example, how much a point is intentionally shifted for exposure. For this reason, if all index values in the same shot region match, this indicates that, when exposing the shot region, all measurement marks in the shot region can be processed under the same exposure condition. Hence, the first apparatus sets a value indicating that batch exposure is to be performed for the shot region in the mark processing field of the shot region in which all index values match.

On the other hand, if there exist two or more types of index values in the same shot region (the index values do not completely match), the first apparatus sets a value indicating that individual mark processing is necessary for mark processing of all position numbers for which index values corresponding to abnormal values are set. With the above-described processing, the coordinates and position numbers of measurement marks included in each shot region and the processing method (shot region batch exposure or individual mark processing) for a measurement mark corresponding to a position numbers are set.

When processing a shot region including individual mark processing, this indicates that only the mark region in the shot region needs to be individually additionally processed. When executing individual mark processing, individual processing different from normal shot region batch exposure needs to be additionally executed by, for example, changing the setting of a masking blade (light shielding plate) and transferring a pattern on the wafer by controlling the apparatus such that only the region that should be individually processed is exposed.

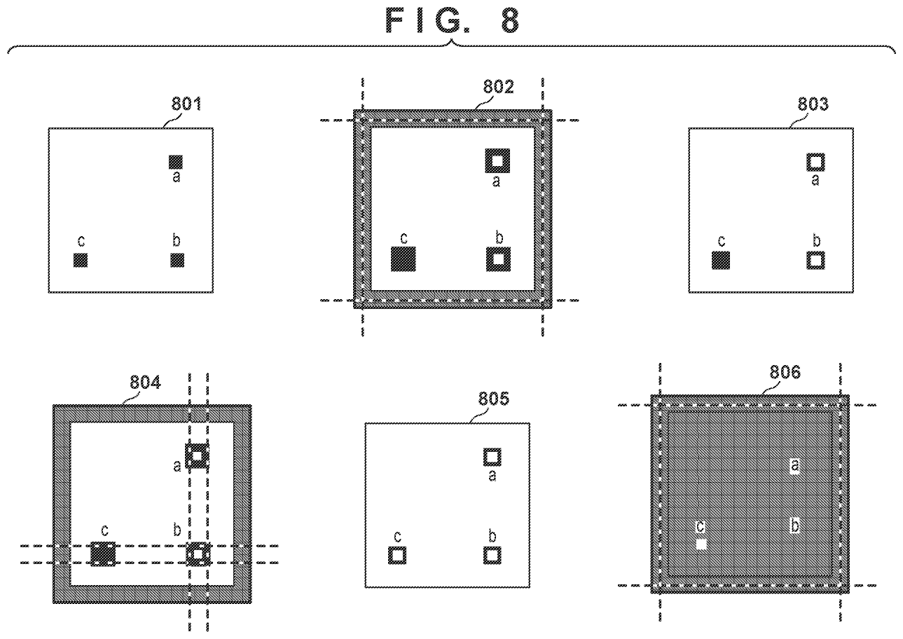

An additional explanation will be made concerning the individual processing. FIG. 8 shows the concept of batch processing and individual processing in the intra shot region measurement mark forming method. Reference numeral 801 denotes an image of a specific shot region on a wafer, and portions a, b, and c are outer marks of BOX-type measurement marks. Reference numeral 802 denotes a reticle pattern, in which black indicates a portion where light is shielded by chrome, and white indicates a portion irradiated with exposure light. Also, portions a, b, and c represent patterns to be transferred to the portions a, b, and c in 801 at the time of shot region batch exposure. A broken line indicates the position of a masking blade (light shielding plate), and the outer side of the broken line is a non-exposure region. Reference numeral 803 denotes a measurement mark forming state in a case where normal shot region batch processing is performed, and indicates a state in which exposure processing is executed while overlaying the reticle pattern in 802 on the wafer pattern in 801. In 803, a BOX-in-BOX type measurement mark is formed in each of the portions a and b.

A procedure of additionally executing individual processing for the portion c in 803 will be described next. Reference numeral 804 denotes a state in which the position of the masking blade (light shielding plate) is set to irradiate only a necessary pattern region on the reticle with exposure light. Also, alignment is performed such that the exposure light irradiation region overlaps a predetermined position on the wafer. In FIG. 8, the portion c in 803 and the portion b in 804 are aligned, and a measurement mark is formed in the portion c (805). The procedure of individually forming a measurement mark in a specific region in a shot region by changing the setting of the masking blade (light shielding plate) has been described above. However, the method of executing individual processing according to the present disclosure is not limited to the above-described procedure. Reference numeral 806 denotes a reticle dedicated to individual processing, in which only the portion c is exposed. In this case, the setting of the masking blade (light shielding plate) is the same as in the batch processing 802, and the contents of the individual processing are contents for performing exposure using a reticle for individual processing. There are various measurement mark forming methods by combining the pattern on the wafer and the reticle pattern. This is information not associated with the gist of the present disclosure, and a detailed description thereof will be omitted.

### Example 1

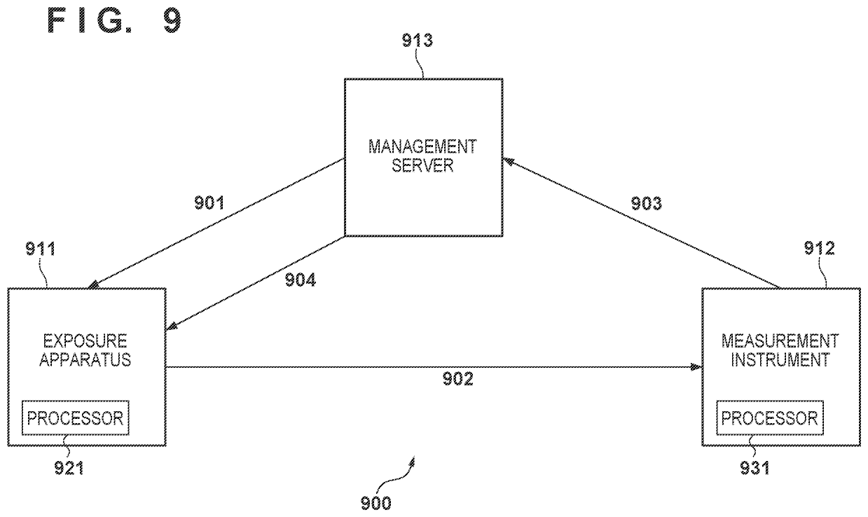

Example 1 will be described below. FIG. 9 schematically shows the configuration of a system 900 serving as a semiconductor manufacturing facility. FIG. 9 shows a procedure of detecting an alignment error of an exposure apparatus 911 and correcting it. First, a management server 913 transmits, to the exposure apparatus 911, identification information to be formed on a wafer, the correspondence definitions of measured values and pattern forming states (Table 3) (second rule), and the position number determination rule (Table 8) (first rule) (901). In this example, the management server 913 and the exposure apparatus 911 function as the first apparatus. This function of the management server 913 may be incorporated in a processor 921 of the exposure apparatus 911. Next, the exposure apparatus 911 produces a measurement wafer in which the identification information of the wafer is reflected on the positions and states of measurement marks. The measurement wafer is sent to a measurement instrument 912 (902), and measurement of the measurement marks is performed by the measurement instrument 912. The coordinate system of the measurement instrument 912 is fixed, and the information is recorded in the management server 913. After the end of the measurement, the measurement result of an alignment error is sent to the management server 913 (903). The management server 913 detects the identification information from the alignment error measurement result, and detects a true alignment error by removing the identification information from the measurement result and updates the alignment offset of the exposure apparatus that has produced the wafer (904). The measurement instrument 912 and the management server 913 function as the second apparatus. This function of the management server 913 may be incorporated in a processor 931 of the measurement instrument 912.

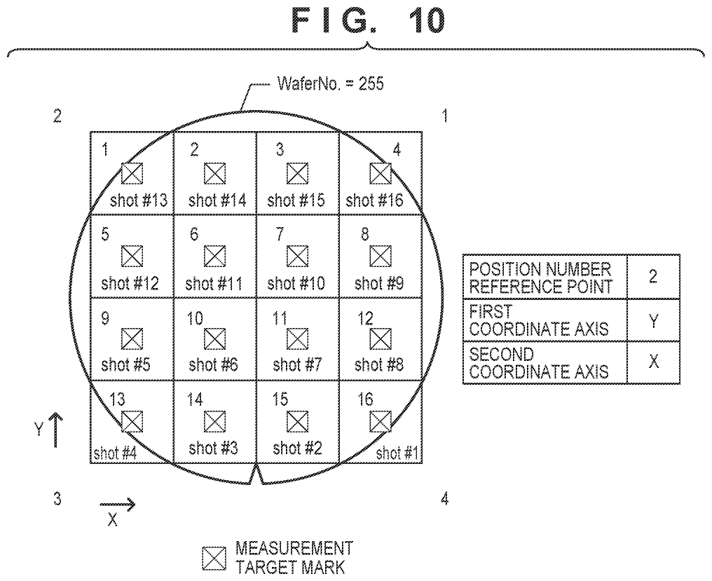

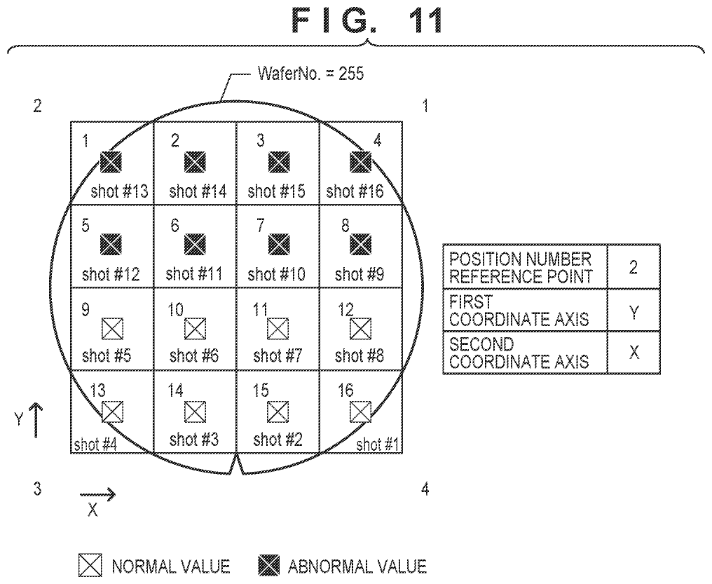

A detailed procedure until the offset updating will be described below. FIG. 10 shows a performance inspection wafer using this embodiment. A 1st pattern for inspecting an alignment accuracy is formed on the wafer. A numerical value surrounded by a circle indicates Shot No. of the exposure apparatus, and a numerical value without a circle indicates a position number. The wafer is managed by a number, and a wafer number “255” is recorded as identification information representing the forming state of measurement marks in the wafer.

In this example, “255” that is Wafer No. is recorded on the wafer as the identification information of the shot regions. Since 16 shot regions are arranged on the produced wafer, Wafer No. is formed by combining two expressions preferably whether a shot region position is normal or abnormal (expression is possible up to 65536).

Table 13 shows the deviation amount (second information) of a shot region (deviated only in the X direction) corresponding to a position number (first information). To express identification information 255 to be recorded, measurement marks for position numbers 1 to 8 are made to deviate by 50 nm in the X direction and exposed. Note that a shot region corresponding to a position number whose index X is 1 is made to deviate by 50 nm in the X direction and exposed. On the other hand, a shot region corresponding to a position number whose index X is 0 is exposed without a deviation amount.

TABLE 13
Identification Information Definition for Inspection Wafer Production

| | Position Number | | | | | | | | | | | | | | | |
|---|---|---|---|---|---|---|---|---|---|---|---|---|---|---|---|---|
| | 1 | 2 | 3 | 4 | 5 | 6 | 7 | 8 | 9 | 10 | 11 | 12 | 13 | 14 | 15 | 16 |
| Index X | 1 | 1 | 1 | 1 | 1 | 1 | 1 | 1 | 0 | 0 | 0 | 0 | 0 | 0 | 0 | 0 |

| | Measured | | Pattern |
|---|---|---|---|
| | Value X | Representative | Forming |
| Classification | Range | Value | State Index |
| Normal | −30 nm ≤ | 0 nm | 0 |
| Value | X ≤ 30 nm | | |
| Abnormal | 30 nm < X | 50 nm | 1 |
| Value | | | |

The above-described pieces of information are shared by the management server 913 and the exposure apparatus 911. In this example, necessary information is distributed from the management server 913 to the exposure apparatus 911. However, the sharing method is not limited to this, and the information may be uploaded from the exposure apparatus 911 to the management server 913 or may be stored in a third storage area and shared.

Next, the exposure apparatus 911 (processor 921) creates definition information used for control of shot region processing. In this example, since each shot region includes one measurement mark whose position is intentionally made to deviate, the measurement mark can be processed by making the whole shot region deviate. The exposure apparatus 911 (processor 921) sets the correspondence relationship between Shot No. and a position number and generates information (Table 14) for exposure processing.

TABLE 14
Definition of Method of Processing Position
Number for Shot Region Processing

| | | Measure- | Measure- | | | |
|---|---|---|---|---|---|---|
| | | ment | ment | | | |
| | | Coordi- | Coordi- | | | |
| Shot | Mark | nates | nates | Position | | Mark |
| No. | No. | X | Y | Number | Index | Processing |
| 1 | 1 | 0 | 0 | 16 | 0 | Shot Batch |
| | | | | | | Exposure |
| 2 | 1 | 0 | 0 | 15 | 0 | Shot Batch |
| | | | | | | Exposure |
| 3 | 1 | 0 | 0 | 14 | 0 | Shot Batch |
| | | | | | | Exposure |
| 4 | 1 | 0 | 0 | 13 | 0 | Shot Batch |
| | | | | | | Exposure |
| 5 | 1 | 0 | 0 | 9 | 0 | Shot Batch |
| | | | | | | Exposure |
| 6 | 1 | 0 | 0 | 10 | 0 | Shot Batch |
| | | | | | | Exposure |
| 7 | 1 | 0 | 0 | 11 | 0 | Shot Batch |
| | | | | | | Exposure |
| 8 | 1 | 0 | 0 | 12 | 0 | Shot Batch |
| | | | | | | Exposure |
| 9 | 1 | 0 | 0 | 8 | 1 | Shot Batch |
| | | | | | | Exposure |
| 10 | 1 | 0 | 0 | 7 | 1 | Shot Batch |
| | | | | | | Exposure |
| 11 | 1 | 0 | 0 | 6 | 1 | Shot Batch |
| | | | | | | Exposure |
| 12 | 1 | 0 | 0 | 5 | 1 | Shot Batch |
| | | | | | | Exposure |
| 13 | 1 | 0 | 0 | 1 | 1 | Shot Batch |
| | | | | | | Exposure |
| 14 | 1 | 0 | 0 | 2 | 1 | Shot Batch |
| | | | | | | Exposure |
| 15 | 1 | 0 | 0 | 3 | 1 | Shot Batch |
| | | | | | | Exposure |
| 16 | 1 | 0 | 0 | 4 | 1 | Shot Batch |
| | | | | | | Exposure |

Next, the exposure apparatus 911 performs exposure processing of the wafer using the information of Table 14. First, the exposure apparatus 911 conveys the wafer to the exposure stage and performs alignment. Subsequently, the exposure apparatus 911 exposes each shot region in accordance with Shot No. At this time, the exposure apparatus 911 confirms the index fields and the mark processing fields of position numbers belonging to the same shot region. In Table 14, normal exposure processing is executed for the first to eighth shot regions. For the ninth to 16th shot regions, the exposure position is made to deviate by 50 nm that is a representative value according to Table 13 such that a mark forming state corresponding to index 1 is obtained. As the result of the above-described processing, a wafer shown in FIG. 11 is produced.

Next, the wafer shown in FIG. 11 is measured by the measurement instrument 912. The measurement instrument 912 measures the deviation amount based on coordinates with respect to position number 13 (lower left corner) in FIG. 11 as the origin, and outputs the measurement result shown in Table 15.

TABLE 15
Measurement Result of Alignment Accuracy
Inspection Wafer (After 2nd Exposure)

| | | Measured | Measured |
|---|---|---|---|
| Coordinates X | Coordinates Y | Value X | Value Y |
| 10 | 10 | 0 | 0 |
| 30 | 10 | 0 | 0 |
| 50 | 10 | 0 | 0 |
| 70 | 10 | 0 | 0 |
| 10 | 30 | 0 | 0 |
| 30 | 30 | 0 | 0 |
| 50 | 30 | 0 | 0 |
| 70 | 30 | 0 | 0 |
| 10 | 50 | 50 | 0 |
| 30 | 50 | 50 | 0 |
| 50 | 50 | 50 | 0 |
| 70 | 50 | 50 | 0 |
| 10 | 70 | 50 | 0 |
| 30 | 70 | 50 | 0 |
| 50 | 70 | 50 | 0 |
| 70 | 70 | 50 | 0 |

Next, the measurement instrument 912 or the management server 913 executes the procedure shown in FIG. 2, thereby converting the coordinates of a measured value into a position number and converting the measurement result into an index for generating identification information and thus obtaining Table 16. After that, the measurement instrument 912 or the management server 913 generates identification information from the position number and measurement mark combination information in accordance with the procedure shown in FIG. 2. Details of conversion processing and generation processing have been described in the embodiment, and a description thereof will be omitted here.

TABLE 16
Measurement Result of Alignment Accuracy Inspection
Wafer (After 2nd Exposure) (After Conversion)

| Position Number | Forming State |
|---|---|
| 13 | 0 |
| 14 | 0 |
| 15 | 0 |
| 16 | 0 |
| 9 | 0 |
| 10 | 0 |
| 11 | 0 |
| 12 | 0 |
| 5 | 1 |
| 6 | 1 |
| 7 | 1 |
| 8 | 1 |
| 1 | 1 |
| 2 | 1 |
| 3 | 1 |
| 4 | 1 |

Next, the measurement instrument 912 or the management server 913 removes an error corresponding to an index value set for each measurement mark from the measurement result in which identification information is recorded as an abnormal value. Since the value after the removal is the true alignment error of the exposure apparatus specified from the identification information, the management server 913 determines, based on this, the necessity of apparatus offset updating. In this example, the true alignment error is 0, and offset updating is unnecessary. If updating is necessary, the apparatus offset is updated at an appropriate timing using an appropriate method.

### Example 2

A method of using the present disclosure for wafer recognition and selection will be described next. Wafer identification information such as a wafer ID is included in processing conditions instructed for the exposure apparatus 911, and slop map information representing the correspondence relationship between the slot number of a wafer storage container and the wafer ID is given to the exposure apparatus, thereby selectively conveying a processing target wafer. Since it is difficult to fix the relationship between the storage container and the wafer, the slop map information needs to be updated every time movement occurs. However, a problem may occur in the updating of the slop map information, and a difference may be generated between the slop map information and the physical positional relationship. In this case, a situation may occur in which conveyance starts while the wafer is erroneously recognized. If a wafer that is not the target is conveyed, a situation in which desired processing cannot be executed due to, for example, generation of a measurement error may occur, or a trouble that measurement is ended, and an inappropriate result including a measurement error is obtained may occur. When the present disclosure is used to identify the conveyed wafer, the trouble caused by the recognition error of the wafer can be prevented.

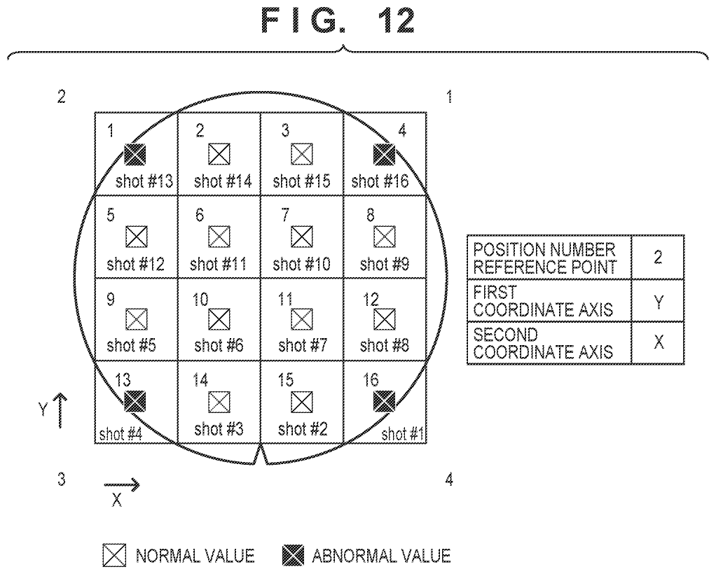

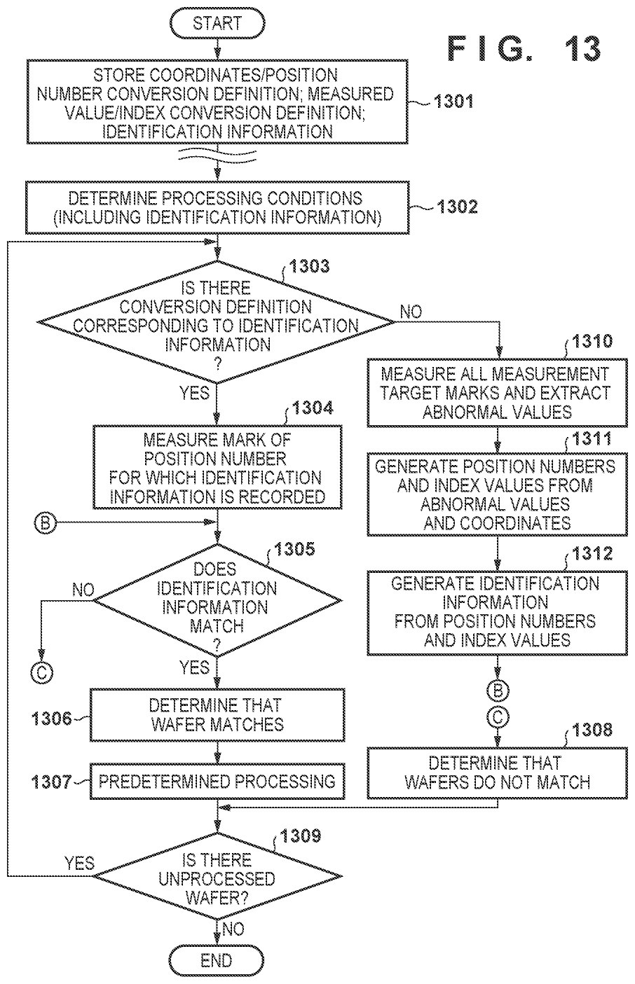

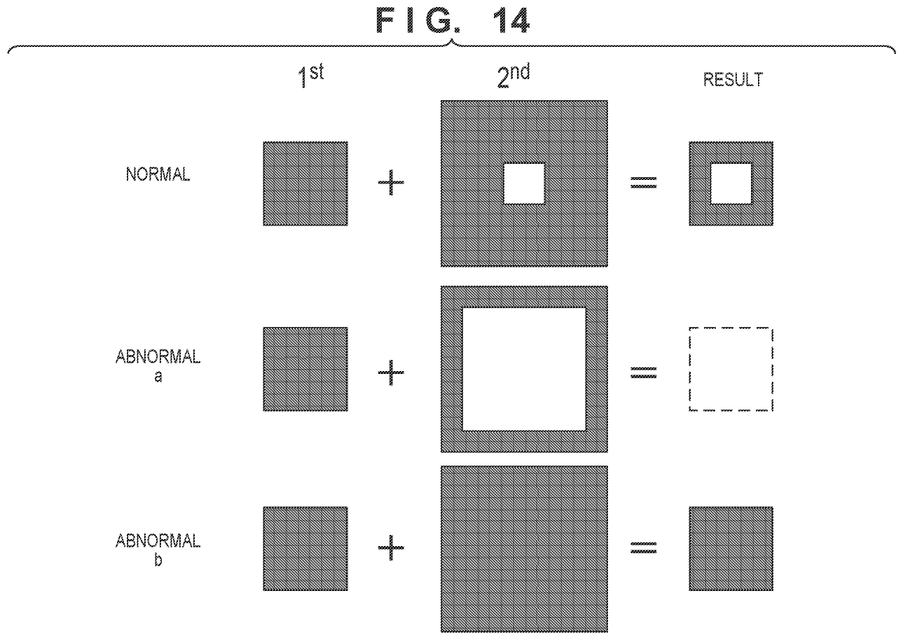

A method of applying to wafer identification processing will be described below. FIG. 12 shows a stage adjustment wafer to which the present disclosure is applied. Shot regions at four corners in the shot region array intentionally change the measurement mark forming state to identify the wafer. A procedure of identifying the wafer will be described with reference to FIG. 13. For the wafer measured once, the system 900 shown in FIG. 9 stores identification information included in a measured value and definition information (described in the embodiment) necessary to obtain the identification information from the measured value.

Even if measurement is not executed, if definition information is received from the outside, the system 900 stores it in association with identification information (step 1301). At a later timing, identification information is designated together with measurement processing conditions (step 1302). The exposure apparatus 911 confirms whether definition information associated with the designated identification information remains (step 1303). If there is no record, the exposure apparatus 911 advances to full-point measurement processing (step 1310), converts the measurement result into position numbers and index values (step 1311), and generates identification information from the result of the conversion (step 1312).

On the other hand, if definition information (description) necessary to obtain identification information from the measured value is stored in association with the identification information, the exposure apparatus 911 specifies the position of the measured value for which the identification information is reflected on the forming state, measures only the mark, and obtains the identification information (step 1304). In FIG. 12, the measurement marks of position numbers 1, 4, 13, and 16 are measured.

Next, the exposure apparatus 911 confirms whether the identification information obtained by wafer measurement matches the identification information designated as the processing condition (step 1305). If these match, the exposure apparatus 911 determines that the conveyed wafer is a processing target (step 1306), and executes desired processing (step 1307). If these do not match, the exposure apparatus 911 determines that the conveyed wafer is not the processing target, and ends the processing of the wafer (step 1308). Here, the exposure apparatus 911 confirms whether an unprocessed wafer remains (step 1309), and if an unprocessed wafer remains, returns to confirmation of the definition information associated with the identification information of the wafer (step 1303). If no unprocessed wafer exists, the exposure apparatus 911 ends the processing. With the above-described processing, even if a wafer conveyance error occurs due to the deviation between the physical position of the wafer and the management information, it is possible to perform desired processing without a recognition error of the wafer.

### Example 3

Concerning a method of reflecting identification information on a measurement mark forming state, a method not described in Examples 1 and 2 will be described. FIG. 14 shows, concerning a position deviation measurement mark, an example of a forming procedure of obtaining a mark forming state in which a measurement result is abnormal by the exposure apparatus 911. In Examples 1 and 2, an example in which a forming state with which a large measured value different from usual is obtained is used as an index has been described. However, a forming state with which measurement fails may be used.

FIG. 14 shows a method of exposing a whole outer box mark to light to eliminate it (abnormality a) and a method of not forming a BOX-in-BOX mark by not exposing an inner mask (abnormality b) in 2nd exposure for forming an inner box mark. A mask pattern shown in 2nd is overlaid on a black box mark (resist residual) portion shown in 1st, thereby changing the pattern forming state on the wafer. In both methods, measurement cannot be performed, a value (9,999 nm) representing that the measurement has failed is set in the measured value, and an index of abnormal value 3 in Table 17 can be recognized. Note that since the value output as the measurement result when the measurement has failed changes depending on the system, values in Table 17 are merely examples and need to be changed in accordance with the applied system.

TABLE 17
Other Position Deviation Mark Formation Examples and Indices

| | Measured Value X | Representative | | Pattern Forming State |
|---|---|---|---|---|
| Classification | Range | Value | | Index |
| Normal Value | −50 nm ≤ X ≤ 50 nm | 0 | nm | 0 |
| Abnormal Value | X < −50 nm | −100 | nm | 1 |
| 1 | | | | |
| Abnormal Value | 50 nm < X | 100 | nm | 2 |
| 2 | | | | |
| Abnormal Value | unmeasurable | 9999 | nm | 3 |
| 3 | | | | |

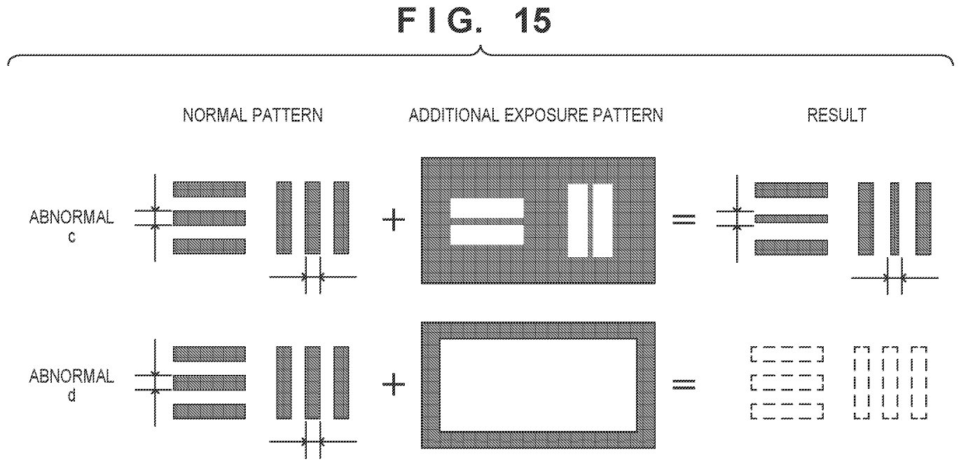

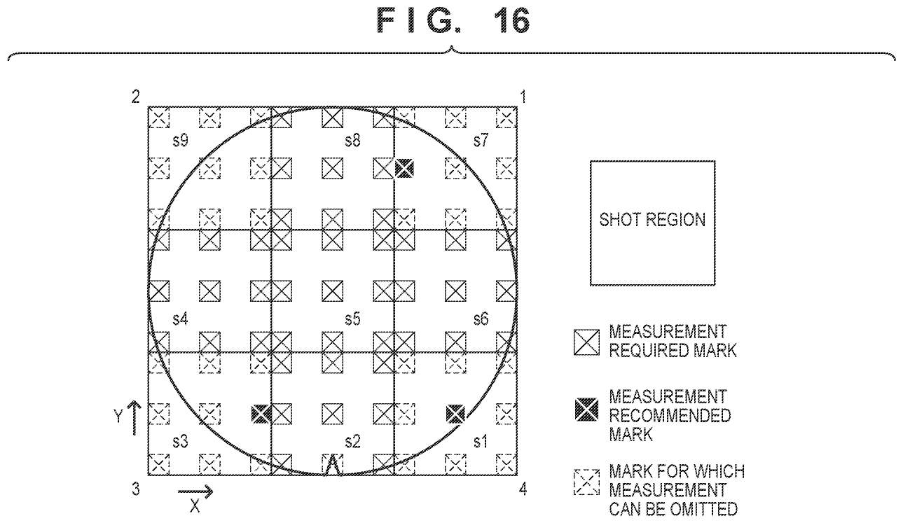

An application example other than position deviation measurement will be described next. FIG. 15 explains a method of changing the line width of a line width measurement mark. FIG. 15 shows a method of overlaying a pattern for changing the line width on a resist pattern formed as a normal pattern on a wafer and exposing the pattern (abnormality c) and a method of exposing a line width measurement mark to light to eliminate it (abnormality d). If the line width is largely changed, it can be regarded as the index of abnormal value 1 in Table 18 based on the measurement result. If the line width measurement mark is eliminated, it can be regarded as the index of abnormal value 2 in Table 18. As described above, it is found that the present disclosure can be applied even to the line width measurement mark. Note that since the value output as the measurement result when the measurement has failed changes depending on the system, values in Table 18 are merely examples and need to be changed in accordance with the applied system.

TABLE 18
Line Width Measurement Mark Formation Examples and Indices

| | Measured Value X | Representative | | Pattern Forming |
|---|---|---|---|---|
| Classification | Range | Value | | State Index |
| Normal Value | 50 nm ≤ X ≤ 150 nm | 100 | nm | 0 |
| Abnormal | X < 50 nm, 150 < X | 25 | nm | 1 |
| Value 1 | | | | |
| Abnormal | unmeasurable | 9999 | nm | 2 |
| Value 2 | | | | |
| | Measured Value Y | Representative | | Pattern Forming |
| Classification | Range | Value | | State Index |
| Normal Value | 50 nm ≤ Y ≤ 150 nm | 100 | nm | 0 |
| Abnormal | Y < 50 nm, 150 ≤ Y | 25 | nm | 1 |
| Value 1 | | | | |
| Abnormal | unmeasurable | 9999 | nm | 2 |

Value 2

### Example 4

A method of forming a plurality of index values in a specific shot region to form identification information and decreasing the number of shot regions for which special exposure processing is performed for identification information formation will be described next. FIG. 16 shows information about a wafer to be created to inspect the performance of the exposure apparatus 911. A number following s indicates a shot region number, and shot regions 2, 4, 5, 6, and 8 include many measurement required marks.

Also, measurement recommended marks exist in shot regions 1, 3, and 7. A measurement recommended mark is a mark that is sometimes omitted because measurement is not essential but is added to the measurement target if apparatus management needs to be enhanced because of occurrence of an event requiring attention. For example, if an overlay failure occurs in latest product lot inspection, a mark which exists near an inspection mark as the cause of the failure and for which measurement can be omitted is temporarily set to the measurement recommended mark, thereby making apparatus management stricter.

A procedure of, when producing the inspection wafer shown in FIG. 16, reflecting 234 that is the number for identifying the wafer on the measurement mark forming state will be described next. First, a shot region to form identification information is determined. Since special exposure processing for forming identification information may affect formation of inspection measurement marks, inspection measurement marks that may be affected are preferably decreased as much as possible. In this example, each shot is ranked, focusing the number of inspection measurement marks.

Table 19 shows the degree of importance of each shot region, and a value obtained by weighting the number of measurement required marks and the number of measurement recommended marks included in each shot region and adding these is calculated as the degree of importance. (In Table 19, the weight of a required mark is 2, and the weight of a recommended mark is 1).

TABLE 19
Identification Information Formation Shot Determination
Table (Shot Importance Determination Table)

| | Number of | Number of | |
|---|---|---|---|
| Shot | Measurement Required | Measurement | Degree of |
| No. | Marks | Recommended Marks | Importance |
| 1 | 0 | 1 | 1 |
| 2 | 8 | 0 | 16 |
| 3 | 0 | 1 | 1 |
| 4 | 9 | 0 | 18 |
| 5 | 9 | 0 | 18 |
| 6 | 9 | 0 | 18 |
| 7 | 0 | 1 | 1 |
| 8 | 9 | 0 | 18 |
| 9 | 0 | 0 | 0 |

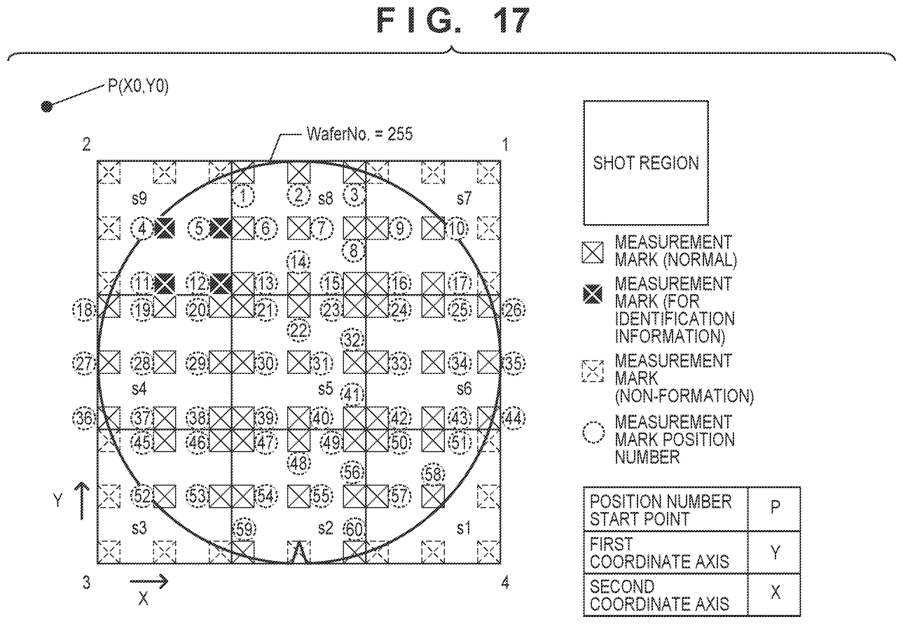

If the degree of importance of each shot region was evaluated, focusing the number of inspection measurement marks, it was judged that using shot region=9 to form identification information is appropriate. A detailed identification information forming method using shot region=9 will be described next. FIG. 17 shows a measurement mark forming state in each shot region on a wafer in which identification information is formed in shot region=9. In shot region=9, intentional deviation amounts are given to measurement marks of position numbers 4, 5, 11, and 12. On the other hand, only normal measurement marks exist in the remaining shot regions, and it is found that normal batch exposure suffices.

Individual mark processing (exposure processing) executed for each mark to form identification information for the four measurement marks of position numbers 4, 5, 11, and 12 in shot region=9 will be described next. If the deviation amounts of the measurement marks at the four points in the X and Y directions are used as index values, eight index values can be used as the elements of identification information. If two types of information are expressed by each index value, 256 types of identification information can be expressed at maximum. Hence, the identification information is expressed by dividing deviation amounts considered as abnormal values in two steps. Table 20 shows the relationship between index values and deviation amounts for expressing wafer number 234 by eight index values.

TABLE 20
Example of Identification Information (234) Generation

| | Index Serial Number | | | | | | | |
|---|---|---|---|---|---|---|---|---|
| | 1 | 2 | 3 | 4 | 5 | 6 | 7 | 8 |
| Identification | 1 | 1 | 1 | 0 | 1 | 0 | 1 | 0 |
| Information | | | | | | | | |
| in Binary | | | | | | | | |
| Notation | | | | | | | | |
| Index Value | 2 | 2 | 2 | 1 | 2 | 1 | 2 | 1 |

| | Measured | | Pattern |
|---|---|---|---|
| | Value | Representative | Forming |
| Classification | Range (nm) | Value | State Index |
| Normal Value | −50 nm ≤ | 0 nm | 0 |
| | V ≤ 50 nm | | |
| Abnormal | V < −50 | −100 nm | 1 |
| Value 1 | | | |
| Abnormal | 50 < V | 100 nm | 2 |
| Value 2 | | | |

Since measurement marks that give intentional deviation amounts in accordance with the index values exist only at four points, eight index values need to be expressed there. Two indices are expressed using the X-direction deviation amount and the Y-direction deviation amount of one measurement mark, thereby expressing eight indices (Table 21).

TABLE 21
Application of Index Values to Position Numbers

| Index Serial | | | |
|---|---|---|---|
| Number | Position Number | X Index Value | Y Index Value |
| 1 | 4 | 2 | |
| 2 | 4 | | 2 |
| 3 | 5 | 2 | |
| 4 | 5 | | 1 |
| 5 | 11 | 2 | |
| 6 | 11 | | 1 |
| 7 | 12 | 2 | |
| 8 | 12 | | 1 |

Furthermore, since the X index value and the Y index value of the same position number are expressed using the X-direction deviation amount and the Y-direction deviation amount of one measurement mark in exposure processing, the pattern of mark processing needs to be defined for each combination of the index X and the index Y (Table 22).

TABLE 22
Position Numbers

| Shot No. | Position Number | Index X, Index Y | Mark Processing |
|---|---|---|---|
| . | . | . | . |
| . | . | . | . |
| . | . | . | . |
| 9 | 4 | 2, 2 | MkExp(2, 2) |
| | 5 | 2, 1 | MkExp(2, 1) |
| | 11 | 2, 1 | MkExp(2, 1) |
| | 12 | 2, 1 | MkExp(2, 1) |
| . | . | . | . |
| . | . | . | . |
| . | . | . | . |

According to the description in Table 22, when exposing shot region=9, the measurement marks corresponding to the position numbers are formed by individual processing. The exposure method (the manner the intentional deviation amount is given) for each mark processing is shown in Table 23.

TABLE 23

| | Additional Deviation Amount in Exposure (nm) | |
|---|---|---|
| Mark Processing | X | Y |
| MkExp(0, 0) | 0 | 0 |
| MkExp(0, 1) | 0 | −100 |
| MkExp(0, 2) | 0 | 100 |
| MkExp(1, 0) | −100 | 0 |
| MkExp(1, 1) | −100 | −100 |
| MkExp(1, 2) | −100 | 100 |
| MkExp(2, 0) | 100 | 0 |
| MkExp(2, 1) | 100 | −100 |
| MkExp(2, 2) | 100 | 100 |

For example, when exposing the measurement mark of position number 4, exposure processing corresponding to mark processing MkExp (2, 2) is executed. Hence, the position is made to deviate by 100 nm in both the X and Y directions, and exposure is performed. Similarly, even for the measurement marks of position numbers 5, 11, and 12, exposure processing according to the definition in Table 23 is performed, thereby reflecting identification information corresponding to the wafer number on the forming state of the measurement marks at four points in shot region=9.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-203527, filed Dec. 20, 2022, which is hereby incorporated by reference herein in its entirety.

1. An acquisition method of acquiring identification information of a substrate from measurement results of a plurality of patterns formed on the substrate, comprising:
specifying the identification information based on first information extracted, in accordance with a first rule, from respective positions of regions where the plurality of patterns respectively exist and second information extracted from respective states of the plurality of patterns in accordance with a second rule.

2. The method according to claim 1, wherein the respective states of the plurality of patterns are respective positions of the plurality of patterns.

3. The method according to claim 1, wherein the respective states of the plurality of patterns are respective line widths of the plurality of patterns.

4. The method according to claim 1, wherein the respective position of the regions where the plurality of patterns respectively exist are respective positions of shot regions where the plurality of patterns respectively exist.

5. The method according to claim 1, wherein the plurality of patterns exist in one shot region, and the respective positions of the regions where the plurality of patterns respectively exist are positions in the one shot region.

6. The method according to claim 1, wherein
the second information includes a plurality of indices converted from the respective states of the plurality of patterns, and
the first information includes information used to determine an order to arrange the plurality of indices to obtain the identification information using the plurality of indices.

7. The method according to claim 6, wherein in the specifying, the identification information is reproduced by combining numbers assigned to the plurality of indices to indicate the order and the plurality of indices.

8. The method according to claim 6, wherein each of the plurality of indices has one of values of not less than 2.

9. The method according to claim 6, wherein each of the plurality of indices has one of values of not less than 3.

10. The method according to claim 1, wherein
the second information includes a plurality of indices converted from the respective states of the plurality of patterns, and
each of the plurality of indices is a value obtained by evaluating a position deviation of each of the plurality of patterns with respect to corresponding one of a plurality of reference positions corresponding to the plurality of patterns.

11. A pattern forming method of forming a plurality of patterns on a substrate, comprising:
determining, in accordance with a first rule, a position to form each of the plurality of patterns on the substrate;
determining, in accordance with a second rule, a state to form each of the plurality of patterns on the substrate; and
forming the plurality of patterns on the substrate in accordance with results determined in the determining the position and the determining the state.

12. A semiconductor manufacturing facility operation method comprising:
forming a plurality of patterns on a substrate in accordance with a pattern forming method defined in claim 11; and
acquiring, in accordance with an acquisition method of acquiring identification information of a substrate from measurement results of a plurality of patterns formed on the substrate, comprising specifying the identification information based on first information extracted, in accordance with a first rule, from respective positions of regions where the plurality of patterns respectively exist and second information extracted from respective states of the plurality of patterns in accordance with a second rule, an identification number from the substrate with the plurality of patterns formed thereon.

13. A processing apparatus having a function of acquiring identification information of a substrate from measurement results of a plurality of patterns formed on the substrate, comprising:
a processor configured to specify the identification information based on first information extracted, in accordance with a first rule, from respective positions of regions where the plurality of patterns respectively exist and second information extracted from respective states of the plurality of patterns in accordance with a second rule.

14. A pattern forming apparatus for forming a plurality of patterns on a substrate, comprising:
a processor configured to control a pattern forming operation such that positions of the substrate, where the plurality of patterns are respectively formed on the substrate are determined in accordance with a first rule, states with which the plurality of patterns are respectively formed on the substrate are determined in accordance with a second rule, and the plurality of patterns are formed on the substrate in accordance with determined results.
